(19) United States
(12) Patent Application Publication
(10) Pub. No.: US 2016/0181233 A1
(43) Pub. Date: Jun. 23, 2016

(54) METAL-INSULATOR-METAL (MIM) CAPACITORS ARRANGED IN A PATTERN TO REDUCE INDUCTANCE, AND RELATED METHODS

(71) Applicant: QUALCOMM Incorporated, San Diego, CA (US)

(72) Inventors: Changhan Hobie Yun, San Diego, CA (US); Je-Hsiung Jeffrey Lan, San Diego, CA (US); Daeik Daniel Kim, Del Mar, CA (US); David Francis Berdy, San Diego, CA (US); Chengjie Zuo, Santee, CA (US); Jonghae Kim, San Diego, CA (US); Niranjan Sunil Mudakatte, San Diego, CA (US); Mario Francisco Velez, San Diego, CA (US); Robert Paul Mikulka, Oceanside, CA (US)

(21) Appl. No.: 14/580,900

(22) Filed: Dec. 23, 2014

(51) Int. Cl. H01L 27/01; H01L 49/02

(52) U.S. Cl. CPC H01L 27/01; H01L 28/40

(57) ABSTRACT

Metal-insulator-metal (MIM) capacitors arranged in a pattern to reduce inductance, and related methods, are disclosed. In one aspect, circuits are provided that employ MIM capacitors coupled in series. The MIM capacitors are arranged in a pattern, wherein a MIM capacitor is placed so as to be electromagnetically adjacent to at least two MIM capacitors, and so that a current of the MIM capacitor flows in a direction opposite or substantially opposite of a direction in which a current of each adjacent MIM capacitor flows. The magnetic field generated at metal connections of each MIM capacitor rotates in an opposite direction of the magnetic field of each electromagnetically adjacent MIM capacitor, and thus a larger proportion of magnetic fields cancel out one another rather than combining, reducing equivalent series inductance (ESL) compared to linear arrangement of MIMs.

### BACKGROUND

I. Field of the Disclosure

The technology of the disclosure relates generally to metal-insulator-metal (MIM) capacitors, and particularly to providing MIMs in a semiconductor die for providing capacitors therein.

II. Background

Mobile communication devices have become commonplace in contemporary society. The greater prevalence of mobile computing devices has accelerated in part because of the increased functionality and versatility of such devices. Specifically, various functions of mobile computing devices rely upon a multitude of radio frequency (RF) capabilities of such devices for successful operation. Thus, it is of particular importance that the circuits within mobile computing devices that implement such RF capabilities are designed to achieve high-quality operation.

In this regard, to achieve such high-quality operation, the requirements of the circuit elements employed in RF circuits are designed according to a more stringent standard. Notably, capacitors are important circuit elements commonly employed in such RF circuits for operations such as filtering, tuning, and signal stabilization. These capacitors are designed to have properties that enable such high quality operation. As non-limiting examples, properties that determine the quality of a capacitor's operation include the capacitance level (C), the efficiency (e.g., the Q factor), the linearity, and the equivalent series inductance (ESL, e.g., parasitic inductance). In particular, the linearity of capacitors employed within RF circuits, where linearity is a measure of how the capacitance level (C) changes in relation to the amount of voltage applied to a capacitor, plays an important role in determining the overall operational quality of the capacitors.

In this regard, improving the linearity of capacitors (e g, minimizing the variation of the capacitance level (C) as the applied voltage level changes), may be involved in designing a high quality capacitor. In particular, metal-insulator-metal (MIM) capacitors are one type of capacitor that may be employed in circuits requiring high-quality capacitors. An exemplary MIM capacitor may be formed by disposing a first metal layer on a substrate, disposing a dielectric layer on top of the first metal layer, and disposing a second metal layer on top of the dielectric layer in a parallel plate type structure.

One way to improve the linearity (e.g., decrease the voltage coefficient of capacitance (VCC)) of a MIM capacitor is to alter the properties of the dielectric layer within the MIM capacitor. Specifically, certain dielectric materials are associated with better linearity, and thus may be employed within a MIM capacitor to improve the capacitor's linearity. Further, the thickness of the dielectric layer within a MIM capacitor is inversely related to the linearity of the MIM capacitor. Thus, a MIM capacitor's linearity may also be improved by increasing the thickness of the dielectric layer. However, altering the properties of the dielectric layer may not improve the linearity of a MIM capacitor to a level needed to achieve a desired quality of operation. Thus, it would be advantageous to further improve the linearity of a MIM capacitor using techniques independent of changes to the dielectric layer.

### SUMMARY OF THE DISCLOSURE

Aspects disclosed in the detailed description include metal-insulator-metal (MIM) capacitors arranged in a pattern to reduce inductance. Related methods are also disclosed. One way to improve the linearity (e.g., decrease the voltage coefficient of capacitance (VCC)) of capacitors within a circuit, including MIM capacitors, is to couple multiple capacitors in series, rather than employing a single capacitor. Specifically, coupling multiple capacitors in series improves the linearity of the serially coupled capacitors having a total capacitance level (C), as compared to a single capacitor having a similar capacitance level (C). However, the serially coupled capacitors have a greater number of metal connections as compared to the single capacitor. Further, multiple capacitors that are serially coupled in this manner are commonly arranged in a linear pattern within a circuit. Such increased metal connections, in conjunction with being arranged in a linear pattern, cause the serially coupled capacitors to have a greater equivalent series inductance (ESL, e.g., parasitic inductance) as compared to the ESL of the single capacitor. In particular, the greater number of metal connections causes the serially coupled capacitors to generate more ESL than the single capacitor upon receiving an equivalent current. Such increased ESL is attributable to a magnetic field generated at metal connections associated with a capacitor in response to a current. Particularly, the linear pattern of the serially coupled capacitors results in a larger proportion of the magnetic fields combining rather than cancelling out one another, thus increasing ESL.

Thus, to improve the linearity of capacitors within circuits while limiting or avoiding a corresponding increase in ESL, in aspects disclosed herein, capacitor circuits (also referred to herein as “circuits”) are provided that employ MIM capacitors that are serially coupled. However, rather than arranging the serially coupled MIM capacitors in a linear pattern in a circuit, such MIM capacitors are arranged in a pattern wherein a MIM capacitor is electromagnetically adjacent to at least two (2) other MIM capacitors. More specifically, arranging the serially coupled MIM capacitors in this pattern involves placing the MIM capacitors in a circuit so that a current flowing through a MIM capacitor flows in a direction that is opposite or substantially opposite of a direction in which a current of each electromagnetically adjacent MIM capacitor flows. In other words, the current flowing within a MIM capacitor flows in an opposite or substantially opposite direction as compared to the current flow of every electromagnetically adjacent MIM capacitor. The magnetic field generated in relation to metal connections of each serially coupled MIM capacitor rotates in an opposite direction of the magnetic field generated in relation to metal connections of each electromagnetically adjacent MIM capacitor. Because the magnetic fields of the electromagnetically adjacent MIM capacitors rotate in this manner, a larger proportion of the magnetic fields cancel out one another rather than combining, thus reducing ESL as compared to ESL generated in a linear arrangement of MIMs. Therefore, arranging the serially coupled MIM capacitors in this pattern improves the linearity of capacitors within circuits while limiting or avoiding a corresponding increase in ESL.

In this regard in one aspect, a capacitor circuit is provided. The capacitor circuit comprises a plurality of MIM capacitors coupled in series and arranged in a circuit in a pattern. Each MIM capacitor among the plurality of MIM capacitors is configured to direct current flow in a direction on an axis that is opposite or substantially opposite of a direction on the axis in which each electromagnetically adjacent MIM capacitor among the plurality of MIM capacitors is configured to direct current flow. A MIM capacitor is electromagnetically adjacent to at least two (2) MIM capacitors.

In another aspect, a capacitor circuit is provided. The capacitor circuit comprises a means for arranging a plurality of MIM capacitors coupled in series on a substrate in a pattern. Each MIM capacitor among the plurality of MIM capacitors is configured to direct current flow in a direction on an axis that is opposite or substantially opposite of a direction on the axis in which each electromagnetically adjacent MIM capacitor among the plurality of MIM capacitors is configured to direct current flow. A MIM capacitor is electromagnetically adjacent to at least two (2) MIM capacitors.

In another aspect, a method of arranging a plurality of MIM capacitors in a circuit is provided. The method comprises disposing each MIM capacitor among a plurality of MIM capacitors coupled in series on a substrate in a pattern. Each MIM capacitor among the plurality of MIM capacitors is configured to direct current flow in a direction on an axis that is opposite or substantially opposite of a direction on the axis in which each electromagnetically adjacent MIM capacitor among the plurality of MIM capacitors is configured to direct current flow. A MIM capacitor is electromagnetically adjacent to at least two (2) MIM capacitors.

### BRIEF DESCRIPTION OF THE FIGURES

FIG. 1 is a cross-sectional diagram of an exemplary capacitor circuit employing two (2) exemplary metal-insulator-metal (MIM) capacitors that are serially coupled according to the prior art;

FIG. 2 is a cross-sectional diagram of an exemplary capacitor circuit employing two (2) vertically stacked MIM capacitors that are serially coupled according to the prior art;

FIG. 3A is a cross-sectional diagram of an exemplary capacitor circuit employing four (4) vertically stacked MIM capacitors that are serially coupled according to the prior art;

FIG. 3B is a top-level view diagram of an exemplary capacitor circuit employing four (4) vertically stacked MIM capacitors that are serially coupled and arranged in a linear pattern according to the prior art;

FIG. 4A is a top-level view diagram of an exemplary capacitor circuit employing four (4) vertically stacked MIM capacitors that are serially coupled and arranged in a pattern to reduce equivalent series inductance (ESL, e.g., parasitic inductance) caused by magnetic fields, wherein a current flowing through a MIM capacitor flows in a direction that is opposite or substantially opposite of a direction in which a current of each electromagnetically adjacent MIM capacitor flows;

FIGS. 4B-4D are cross-sectional diagrams of the capacitor circuit in FIG. 4A employing four (4) vertically stacked MIM capacitors that are serially coupled and arranged in the pattern illustrated in FIG. 4A;

FIG. 5 is a top-level view diagram of an exemplary capacitor circuit employing six (6) vertically stacked MIM capacitors that are serially coupled and arranged in the pattern illustrated in FIG. 4A;

FIG. 6 is a top-level view diagram of an exemplary capacitor circuit employing eight (8) vertically stacked MIM capacitors that are serially coupled and arranged in the pattern illustrated in FIG. 4A;

FIG. 7 is a flowchart of an exemplary process that can be employed to arrange the four (4), six (6), or eight (8) vertically stacked MIM capacitors in FIG. 4, 5, or 6, respectively, in the pattern;

FIG. 8 is a top-level view diagram of a capacitor circuit employing six (6) vertically stacked MIM capacitors that are serially coupled and arranged in an alternative pattern, wherein a current flowing through a MIM capacitor flows in a direction that is opposite or substantially opposite of a direction in which a current of each electromagnetically adjacent MIM capacitor flows;

FIG. 9 is a flowchart of an exemplary process employed to arrange the six (6) vertically stacked MIM capacitors in FIG. 8 in the alternative pattern;

FIG. 10 is a top-level view diagram of an exemplary capacitor circuit employing eight (8) vertically stacked MIM capacitors that are serially coupled and arranged in an alternative pattern, wherein a current flowing through a MIM capacitor flows in a direction that is opposite or substantially opposite of a direction in which a current of each electromagnetically adjacent MIM capacitor flows;

FIG. 11 is a flowchart of an exemplary process employed to arrange the eight (8) vertically stacked MIM capacitors in FIG. 10 in the alternative pattern;

FIG. 12A is three-dimensional view diagram of an exemplary capacitor circuit employing four (4) vertically stacked MIM capacitors in a coreless substrate technology and arranged in a pattern to reduce ESL caused by magnetic fields;

FIG. 12B is a top-level view diagram of the exemplary capacitor circuit employing the four (4) vertically stacked MIM capacitors in the coreless substrate technology in FIG. 12A; and

FIG. 13 is a block diagram of an exemplary processor-based system that can include the capacitor circuit in FIG. 4A employing the four (4) vertically stacked MIM capacitors that are serially coupled and arranged in a pattern to reduce ESL caused by the magnetic fields.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include metal-insulator-metal (MIM) capacitors arranged in a pattern to reduce inductance. Related methods are also disclosed. One way to improve the linearity (e.g., decrease the voltage coefficient of capacitance (VCC)) of capacitors within a circuit, including MIM capacitors, is to couple multiple capacitors in series, rather than employing a single capacitor. Specifically, coupling multiple capacitors in series improves the linearity of the serially coupled capacitors having a total capacitance level (C), as compared to a single capacitor having a similar capacitance level (C). However, the serially coupled capacitors have a greater number of metal connections as compared to the single capacitor. Further, multiple capacitors that are serially coupled in this manner are commonly arranged in a linear pattern within a circuit. Such increased metal connections, in conjunction with being arranged in a linear pattern, cause the serially coupled capacitors to have a greater equivalent series inductance (ESL, e.g., parasitic inductance) as compared to the ESL of the single capacitor. In particular, the greater number of metal connections causes the serially coupled capacitors to generate more ESL than the single capacitor upon receiving an equivalent current. Such increased ESL is attributable to a magnetic field generated at metal connections associated with a capacitor in response to a current. Particularly, the linear pattern of the serially coupled capacitors results in a larger proportion of the magnetic fields combining rather than cancelling out one another, thus increasing ESL.

Thus, to improve the linearity of capacitors within circuits while limiting or avoiding a corresponding increase in ESL, in aspects disclosed herein, capacitor circuits (also referred to herein as “circuits”) are provided that employ MIM capacitors that are serially coupled. However, rather than arranging the serially coupled MIM capacitors in a linear pattern in a circuit, such MIM capacitors are arranged in a pattern wherein a MIM capacitor is electromagnetically adjacent to at least two (2) other MIM capacitors. More specifically, arranging the serially coupled MIM capacitors in this pattern involves placing the MIM capacitors in a circuit so that a current flowing through a MIM capacitor flows in a direction that is opposite or substantially opposite of a direction in which a current of each electromagnetically adjacent MIM capacitor flows. In other words, the current flowing within a MIM capacitor flows in an opposite or substantially opposite direction as compared to the current flow of every electromagnetically adjacent MIM capacitor. The magnetic field generated in relation to metal connections of a serially coupled MIM capacitor rotates in an opposite direction of the magnetic field generated in relation to metal connections of each electromagnetically adjacent MIM capacitor. Because the magnetic fields of the electromagnetically adjacent MIM capacitors rotate in this manner, a larger proportion of the magnetic fields cancel out one another rather than combining, thus reducing ESL as compared to ESL generated in a linear arrangement of MIMs. Therefore, arranging the serially coupled MIM capacitors in this pattern improves the linearity of capacitors within circuits while limiting or avoiding a corresponding increase in ESL.

Notably, as will be seen throughout this disclosure, the MIM capacitors arranged in the sinusoidal-shape pattern that are electromagnetically adjacent are also physically adjacent. However, alternative aspects may include MIM capacitors arranged in the sinusoidal-shape pattern that are electromagnetically adjacent, but not physically adjacent.

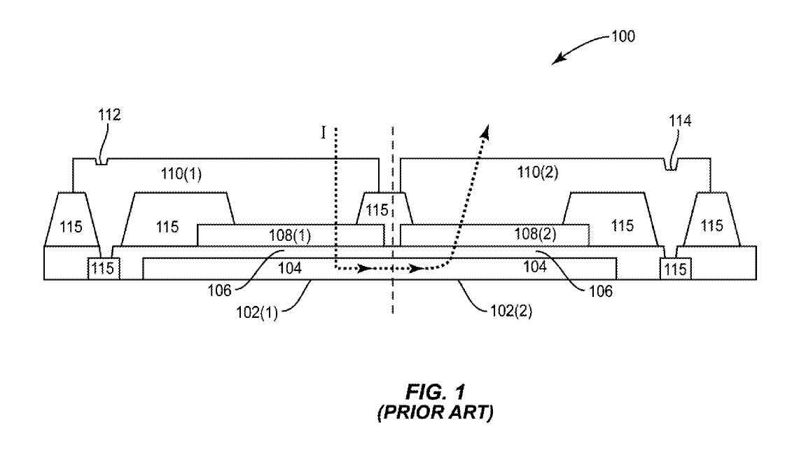

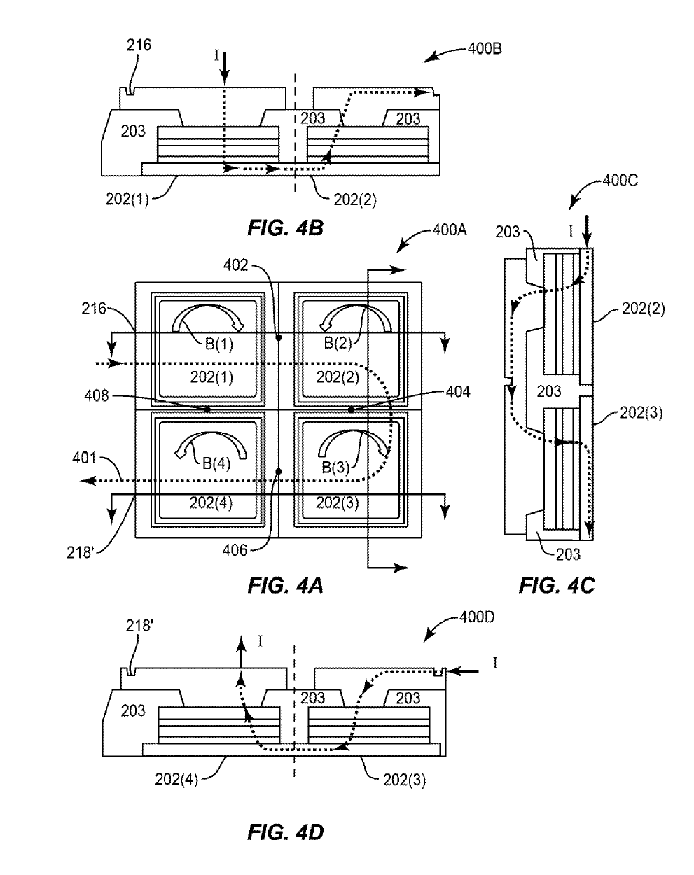

Before discussing specific details of MIM capacitors arranged in a sinusoidal-shape pattern to reduce inductance starting at FIG. 4A, MIM capacitors and typical arrangements within circuits are first described. In this regard, FIG. 1 illustrates a cross-sectional diagram of an exemplary circuit 100 employing two (2) MIM capacitors 102(1), 102(2), which are serially coupled according to the prior art. The MIM capacitor 102(1) includes a first metal layer 104 disposed on a substrate (not shown). The MIM capacitor 102(1) also includes a dielectric layer 106 disposed on top of the first metal layer 104, and a second metal layer 108(1) disposed on top of the dielectric layer 106. In this manner, the MIM capacitor 102(1) is formed using the first metal layer 104, the dielectric layer 106, and the second metal layer 108(1). Because the structure of the MIM capacitor 102(1) includes the first metal layer 104, the dielectric layer 106, and the second metal layer 108(1), the MIM capacitor 102(1) may be referred to as a single layer MIM capacitor. Further, a port metal 110(1) is disposed on top of the second metal layer 108(1) to provide a first port 112 configured to provide a current (I) to the MIM capacitor 102(1).

With continuing reference to FIG. 1, the MIM capacitor 102(2) is formed using the same first metal layer 104 employed in the MIM capacitor 102(1). The MIM capacitor 102(2) also shares the dielectric layer 106 disposed on top of the first metal layer 104 with the MIM capacitor 102(1). However, rather than sharing the second metal layer 108(1) with the MIM capacitor 102(1), the MIM capacitor 102(2) includes a second metal layer 108(2) disposed on top of the dielectric layer 106. Thus, the MIM capacitor 102(2) is formed using the first metal layer 104, the dielectric layer 106, and the second metal layer 108(2), and may therefore also be referred to as a single layer MIM capacitor. Further, a port metal 110(2) is disposed on top of the second metal layer 108(2) to provide a second port 114 configured to provide a current (I) from the MIM capacitor 102(2). Notably, an insulating layer 115 is disposed at various locations in the circuit 100, wherein the insulating layer 115 is configured to separate particular layers of the MIM capacitors 102(1), 102(2) from other circuit elements. In this manner, by sharing the first metal layer 104 while employing separate second metal layers 108(1) and 108(2), respectively, the MIM capacitors 102(1), 102(2) are coupled to one another in series. Being serially coupled requires the current (I) to flow through each respective layer of the MIM capacitors 102(1), 102(2) to traverse from the first port 112 to the second port 114. By being serially coupled, the linearity of the MIM capacitors 102(1), 102(2) having a total capacitance level (C) may be improved as compared to a single capacitor having a similar capacitance level (C).

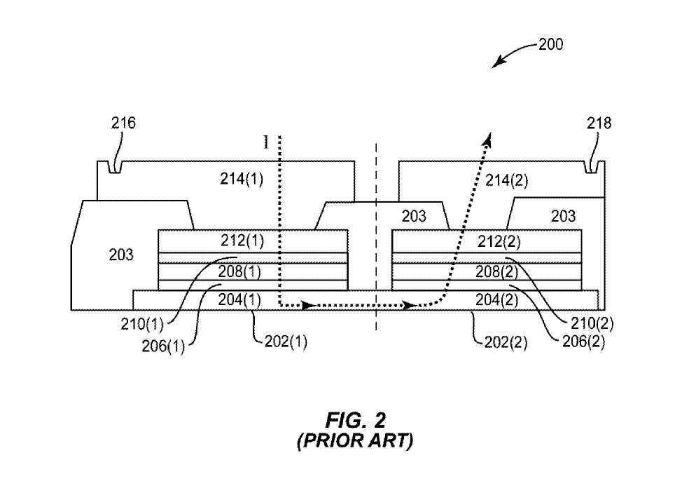

In addition to the MIM capacitors 102(1), 102(2) in FIG. 1, other MIM capacitors may employ alternative structures so as to achieve improved linearity while achieving reduced circuit area. In this regard, FIG. 2 illustrates a cross-sectional diagram of an exemplary circuit 200 employing two (2) vertically stacked MIM capacitors 202(1), 202(2), which are serially coupled according to the prior art. Notably, an insulating layer 203 is disposed at various locations in the circuit 200, wherein the insulating layer 203 is configured to separate particular layers of the MIM capacitors 202(1), 202(2) from other circuit elements. The vertically stacked MIM capacitor 202(1) includes a first metal layer 204(1) disposed on a substrate (not shown). The vertically stacked MIM capacitor 202(1) also includes a first dielectric layer 206(1) disposed on top of the first metal layer 204(1), and a second metal layer 208(1) disposed on top of the first dielectric layer 206(1). Further, the vertically stacked MIM capacitor 202(1) includes a second dielectric layer 210(1) disposed on top of the second metal layer 208(1), and a third metal layer 212(1) disposed on top of the second dielectric layer 210(1). Thus, the vertically stacked MIM capacitor 202(1) is formed using the first metal layer 204(1), the first dielectric layer 206(1), the second metal layer 208(1), the second dielectric layer 210(1), and the third metal layer 212(1). A port metal 214(1) is disposed on top of the third metal layer 212(1) to provide a first port 216 configured to provide a current (I) to the vertically stacked MIM capacitor 202(1). Notably, by vertically stacking multiple layers in this manner, the vertically stacked MIM capacitor 201(1) is effectively equivalent to two (2) single layer MIM capacitors, such as the MIM capacitors 102(1), 102(2) in FIG. 1, while only requiring circuit area of approximately one (1) single layer MIM capacitor.

With continuing reference to FIG. 2, the vertically stacked MIM capacitor 202(2) is formed using the same first metal layer 204(1) employed in the vertically stacked MIM capacitor 202(1). However, the vertically stacked MIM capacitor 202(2) employs a first dielectric layer 206(2), a second metal layer 208(2), a second dielectric layer 210(2), and a third metal layer 212(2) separate from similar elements in the vertically stacked MIM capacitor 202(1). A port metal 214(2) is disposed on top of the third metal layer 212(2) to provide a second port 218 configured to provide a current (I) from the vertically stacked MIM capacitor 202(2). Similar to the vertically stacked MIM capacitor 202(1), the vertically stacked MIM capacitor 202(2) is effectively equivalent to two (2) single layer MIM capacitors, while only requiring a circuit area of approximately one (1) single layer MIM capacitor. Further, by sharing the first metal layer 204(1) while employing separate second metal layers 208(1), 208(2) and separate third metal layers 212(1), 212(2), respectively, the vertically stacked MIM capacitors 202(1), 202(2) are coupled to one another in series. Being serially coupled requires the current (I) to flow through each respective layer of the vertically stacked MIM capacitors 202(1), 202(2) to traverse from the first port 216 to the second port 218. When serially coupled as described, the vertically stacked MIM capacitors 202(1), 202(2) are effectively equivalent to four (4) single layer MIM capacitors, while only using a circuit area of approximately two (2) single layer MIM capacitors. Thus, serially coupling the vertically stacked MIM capacitors 202(1), 202(2) having a total capacitance (C) in this manner may allow for improved linearity, while requiring less circuit area as compared to multiple single layer MIM capacitors having a similar total capacitance (C).

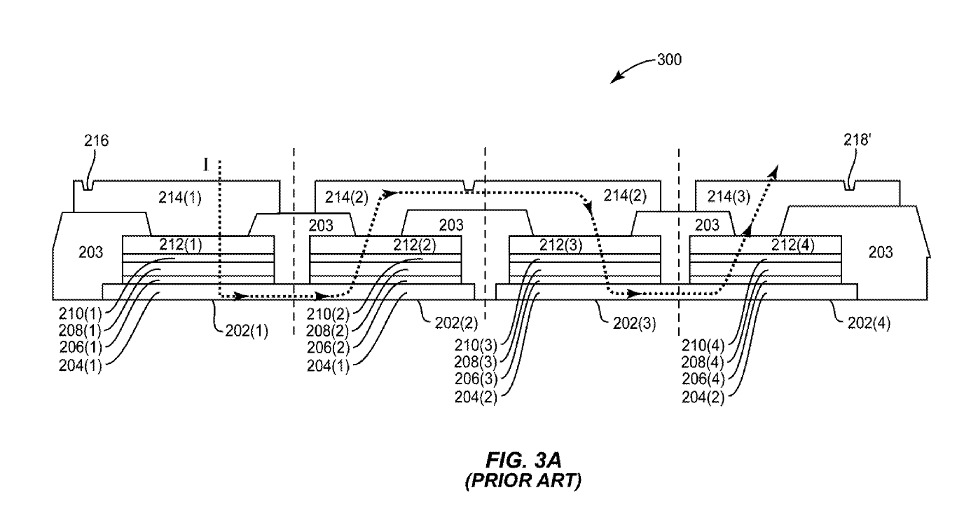

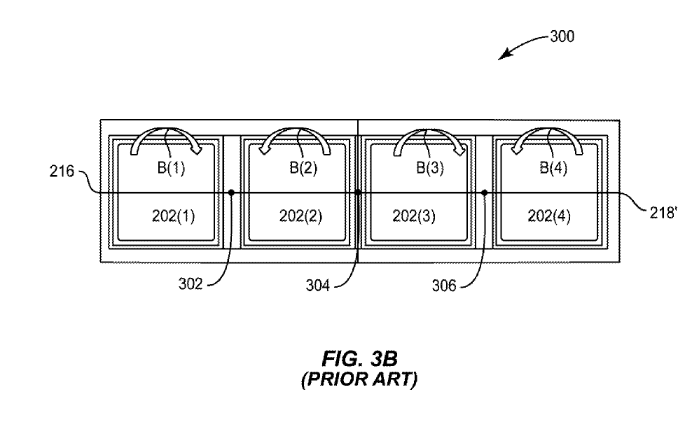

While the circuit 200 in FIG. 2 employs the two (2) vertically stacked MIM capacitors 202(1), 202(2) coupled in series, other circuits may employ a greater number of vertically stacked MIM capacitors. In this regard, FIG. 3A illustrates a cross-sectional diagram of an exemplary capacitor circuit 300 employing four (4) vertically stacked MIM capacitors 202(1)-202(4), which are serially coupled according to the prior art. Notably, the vertically stacked MIM capacitors 202(1)-202(2) include the insulating layer 203, the first metal layer 204(1), the first dielectric layers 206(1), 206(2), the second metal layers 208(1), 208(2), the second dielectric layers 210(1), 210(2), the third metal layers 212(1), 212(2), and the port metals 214(1), 214(2) in FIG. 2, and thus, are not re-described herein. However, while the vertically stacked MIM capacitor 202(1) in the circuit 300 includes the first port 216 in FIG. 2, the vertically stacked MIM capacitor 202(2) does not include the second port 218. Rather, because the circuit 300 employs the vertically stacked MIM capacitors 202(3), 202(4) serially coupled to the vertically stacked MIM capacitors 202(1), 202(2), a second port 218′ is included in the vertically stacked MIM capacitor 202(4) using a port metal 214(3).

In this regard, with continuing reference to FIG. 3A, the vertically stacked MIM capacitor 202(3) includes a first metal layer 204(2) disposed on a substrate (not shown). The vertically stacked MIM capacitor 202(3) also includes a first dielectric layer 206(3) disposed on top of the first metal layer 204(2), and a second metal layer 208(3) disposed on top of the first dielectric layer 206(3). Further, the vertically stacked MIM capacitor 202(3) includes a second dielectric layer 210(3) disposed on top of the second metal layer 208(3), and a third metal layer 212(3) disposed on top of the second dielectric layer 210(3). Thus, the vertically stacked MIM capacitor 202(3) is formed using the first metal layer 204(2), the first dielectric layer 206(3), the second metal layer 208(3), the second dielectric layer 210(3), and the third metal layer 212(3). Further, the port metal 214(2) is disposed on top of the third metal layer 212(3), thus serially coupling the vertically stacked MIM capacitor 202(3) to the vertically stacked MIM capacitor 202(2).

With continuing reference to FIG. 3A, the vertically stacked MIM capacitor 202(4) is formed using the same first metal layer 204(2) employed in the vertically stacked MIM capacitor 202(3). However, the vertically stacked MIM capacitor 202(4) employs a first dielectric layer 206(4), a second metal layer 208(4), a second dielectric layer 210(4), and a third metal layer 212(4) separate from similar elements in the vertically stacked MIM capacitors 202(1)-202(3). The port metal 214(3) is disposed on top of the third metal layer 212(4) to provide the second port 218′ that is configured to provide a current (I) from the vertically stacked MIM capacitor 202(4). Similar to the vertically stacked MIM capacitors 202(1)-202(2), by sharing the first metal layer 204(2) while employing separate second metal layers 208(3), 208(3) and separate third metal layers 212(3), 212(4), respectively, the vertically stacked MIM capacitors 202(3), 202(4) are coupled to one another in series. Additionally, because the vertically stacked MIM capacitor 202(2) is serially coupled to the vertically stacked MIM capacitor 202(3), the vertically stacked MIM capacitors 202(1)-202(4) are serially coupled. Being serially coupled requires the current (I) to flow through each respective layer of the vertically stacked MIM capacitors 202(1)-202(4) to traverse from the first port 216 to the second port 218′.

When multiple vertically stacked MIM capacitors are serially coupled, as are the vertically stacked MIM capacitors 202(1)-202(4) in FIG. 3A, such capacitors are commonly arranged in a linear pattern within a circuit. In this regard, FIG. 3B is a top-level view diagram of the capacitor circuit 300 in FIG. 3A employing the vertically stacked MIM capacitors 202(1)-202(4) arranged in a linear pattern according to the prior art. Because the vertically stacked MIM capacitors 202(1)-202(4) are serially coupled, the circuit 300 includes increased metal connections as compared to a circuit employing a single capacitor with a capacitance level (C) similar to the total capacitance level (C) of the circuit 300. Such increased metal connections, in conjunction with being arranged in the linear pattern illustrated in FIG. 3B, cause the circuit 300 to have a greater ESL (e.g., parasitic inductance) as compared to the ESL of a circuit with a single capacitor. In particular, the greater number of metal connections causes the vertically stacked MIM capacitors 202(1)-202(4) to generate more ESL than a single capacitor upon receiving an equivalent current (I).

In this regard, with continued reference to FIG. 3B, such increased ESL is attributable to magnetic fields B(1)-B(4) generated at metal connections associated with each corresponding vertically stacked MIM capacitor 202(1)-202(4) upon receiving the current (I). The linear pattern results in a larger proportion of the magnetic fields B(1)-B(4) combining rather than cancelling out one another, thus increasing ESL. In particular, the magnetic fields B(1), B(2) are generated in electromagnetically adjacent vertically stacked MIM capacitors 202(1), 202(2), and rotate toward one another (e.g., the magnetic field B(1) rotates clockwise while the magnetic field B(2) rotates counterclockwise). Thus, the magnetic fields B(1), B(2) combine, thereby increasing ESL at a point 302. Conversely, the magnetic fields B(2), B(3) are generated in electromagnetically adjacent vertically stacked MIM capacitors 202(2), 202(3), and rotate away from one another (e.g., the magnetic field B(2) rotates counter-clockwise while the magnetic field B(3) rotates clockwise). Thus, the magnetic fields B(2), B(3) cancel out one another, thereby decreasing ESL at a point 304. Further, similar to the magnetic fields B(1), B(2), the magnetic fields B(3), B(4) are generated in electromagnetically adjacent vertically stacked MIM capacitors 202(3), 202(4), and rotate toward one another (e.g., the magnetic field B(3) rotates clockwise while the magnetic field B(4) rotates counterclockwise). Thus, the magnetic fields B(3), B(4) combine, thereby increasing ESL at a point 306. Because the ESL is increased at the two (2) points 302, 306, and only decreased at one (1) point 304, the overall ESL of the circuit 300 increases due to the serial coupling in conjunction with the linear arrangement of the vertically stacked MIM capacitors 202(1)-202(4). Therefore, it would be advantageous to serially couple the vertically stacked MIM capacitors 202(1)-202(4) to improve linearity while limiting or avoiding a corresponding increase in ESL.

In this regard, FIG. 4A illustrates a top-level view diagram of an exemplary capacitor circuit 400A employing the vertically stacked MIM capacitors 202(1)-202(4) in FIG. 3A. In this aspect, the vertically stacked MIM capacitors 202(1)-202(4) are connected in series and arranged in a pattern 401 to reduce ESL (e.g., parasitic inductance) caused by the magnetic fields B(1)-B(4). In this aspect, the pattern 401 is a sinusoidal-shape pattern. Notably, in other aspects, the vertically stacked MIM capacitors 202(1)-202(4) may be serially coupled and arranged in the pattern 401 and achieve similar functionality. Further, cross-sectional diagrams 400B, 400C, and 400D of the vertically stacked MIM capacitors 202(1)-202(4) are illustrated in FIGS. 4B, 4C, and 4D, respectively, to provide clarification concerning the direction of current (I) flow. Particularly, the cross-sectional diagrams 400B, 400C, and 400D illustrate the same elements and serial connections as described in FIG. 3A, and thus will not be re-described herein. In this manner, each vertically stacked MIM capacitor 202(1)-202(4) is configured to direct current (I) flow in a direction on an axis that is opposite or substantially opposite of a direction on the axis in which each electromagnetically adjacent vertically stacked MIM capacitor 202(1)-202(4) is configured to direct current (I) flow. In this aspect, each vertically stacked MIM capacitor 202(1)-202(4) is configured to direct current (I) flow on the vertical axis. However, alternative aspects may be configured to direct current (I) flow on other axes. Further, a vertically stacked MIM capacitor 202(1)-202(4) is electromagnetically adjacent to at least two (2) other vertically stacked MIM capacitors 202(1)-202(4).

With continuing reference to FIG. 4A, to achieve the pattern 401 in the capacitor circuit 400A employing the vertically stacked MIM capacitors 202(1)-202(4), the vertically stacked MIM capacitor 202(1) is disposed on a substrate (not shown) electromagnetically adjacent to the vertically stacked MIM capacitors 202(2), 202(4). Similarly, the vertically stacked MIM capacitor 202(2) is disposed electromagnetically adjacent to the vertically stacked MIM capacitors 202(1), 202(3) on the substrate, and is serially connected to the vertically stacked MIM capacitor 202(1). The vertically stacked MIM capacitor 202(3) is disposed electromagnetically adjacent to the vertically stacked MIM capacitors 202(2), 202(4) on the substrate, and is serially connected to the vertically stacked MIM capacitor 202(2). Further, the vertically stacked MIM capacitor 202(4) is disposed electromagnetically adjacent to the vertically stacked MIM capacitors 202(1), 202(3) on the substrate, and is serially connected to the vertically stacked MIM capacitor 202(3).

With continuing reference to FIG. 4A, by arranging the vertically stacked MIM capacitors 202(1)-202(4) in the pattern 401 as described above, the ESL attributable to the magnetic fields B(1)-B(4) is reduced as compared to the similar ESL generated as a result of the linear arrangement in FIG. 3B. Particularly, the pattern 401 results in a larger proportion of the magnetic fields B(1)-B(4) cancelling out one another rather than combining, thus decreasing ESL upon the circuit 400A receiving the current (I). In particular, the magnetic fields B(1), B(2) are generated in electromagnetically adjacent vertically stacked MIM capacitors 202(1), 202(2), and rotate toward one another (e.g., the magnetic field B(1) rotates clockwise while the magnetic field B(2) rotates counterclockwise). Thus, the magnetic fields B(1), B(2) combine, thereby increasing ESL at a point 402. Conversely, the magnetic fields B(2), B(3) are generated in electromagnetically adjacent vertically stacked MIM capacitors 202(2), 202(3), and rotate away from one another (e.g., the magnetic field B(2) rotates counterclockwise while the magnetic field B(3) rotates clockwise). Thus, the magnetic fields B(2), B(3) cancel out one another, thereby decreasing ESL at a point 404. Further, the magnetic fields B(3), B(4) are generated in electromagnetically adjacent vertically stacked MIM capacitors 202(3), 202(4), and rotate away from one another (e.g., the magnetic field B(3) rotates clockwise while the magnetic field B(4) rotates counterclockwise). Thus, the magnetic fields B(3), B(4) cancel out one another, thereby decreasing ESL at a point 406. Additionally, the magnetic fields B(1), B(4) rotate away from one another. Thus, the magnetic fields B(1), B(4) cancel out one another, thereby decreasing ESL at a point 408. Because the ESL is decreased at the three (3) points 404, 406, and 408, and only increased at one (1) point 402, the overall ESL of the circuit 400A decreases due to the serial connection in conjunction with the sinusoidal-shape pattern of the vertically stacked MIM capacitors 202(1)-202(4). Therefore, connecting the vertically stacked MIM capacitors 202(1)-202(4) in series improves the linearity of the vertically stacked MIM capacitors 202(1)-202(4), while the arrangement in the pattern 401 reduces a corresponding increase in ESL as compared to the linear pattern.

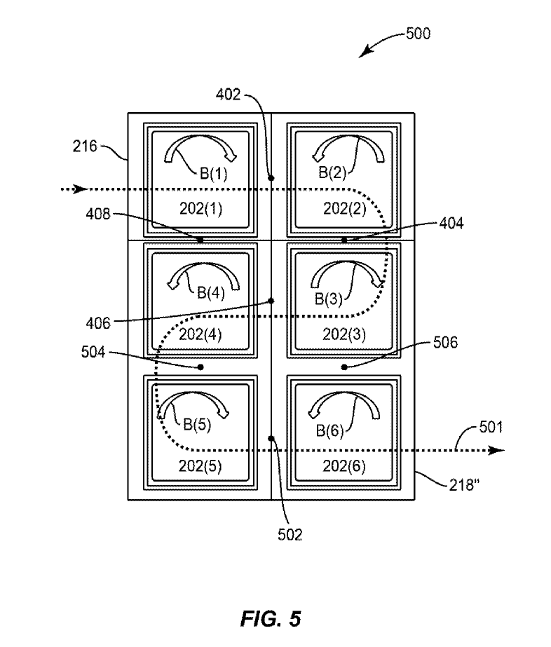

Notably, the pattern 401 described in relation to FIG. 4A may achieve similar ESL reduction in circuits employing any even number (N) of vertically stacked MIM capacitors 202(1)-202(N). For example, FIG. 5 illustrates a top-level view diagram of an exemplary capacitor circuit 500 employing six (6) vertically stacked MIM capacitors 202(1)-202(6), which are connected in series and arranged in a pattern 501 similar to the pattern 401 in FIG. 4A (e.g., a sinusoidal-shape pattern). The vertically stacked MIM capacitors 202(1)-202(4) are included in the circuit 500 in the same configuration as described in relation to the circuit 400A in FIG. 4A, and thus are not re-described herein. In this manner, the vertically stacked MIM capacitor 202(5) is disposed electromagnetically adjacent to the vertically stacked MIM capacitors 202(4), 202(6) on the substrate (not shown), and is serially connected to the vertically stacked MIM capacitor 202(4). Additionally, the vertically stacked MIM capacitor 202(6) is disposed electromagnetically adjacent to the vertically stacked MIM capacitors 202(3), 202(5) on the substrate, and is serially connected to the vertically stacked MIM capacitor 202(5). Using this configuration, the first port 216 is still provided in the vertically stacked MIM capacitor 202(1), but a second port 218″ is provided in the vertically stacked MIM capacitor 202(6).

With continuing reference to FIG. 5, the pattern 501 results in a larger proportion of magnetic fields B(1)-B(6) cancelling out one another rather than combining. Particularly, in addition to the properties of the magnetic fields B(1)-B(4) previously described in FIG. 4A, the magnetic fields B(5), B(6) are generated in electromagnetically adjacent, vertically stacked MIM capacitors 202(5), 202(6), and rotate toward one another. Thus, the magnetic fields B(5), B(6) combine, thereby increasing ESL at a point 502. Conversely, the magnetic fields B(4), B(5) are generated in electromagnetically adjacent, vertically stacked MIM capacitors 202(4), 202(5), and rotate away from one another. Thus, the magnetic fields B(4), B(5) cancel out one another, thereby decreasing ESL at a point 504. Further, similar to the magnetic fields B(4), B(5), the magnetic fields B(3), B(6) are generated in electromagnetically adjacent, vertically stacked MIM capacitors 202(3), 202(6), and rotate away from one another. Thus, the magnetic fields B(3), B(6) cancel out one another, thereby decreasing ESL at a point 506. Because the ESL is decreased at the five (5) points 404, 406, 408, 504, and 506, and only increased at the two (2) points 402, 502, the overall ESL of the circuit 500 decreases due to the serial connection in conjunction with the pattern 501 of the vertically stacked MIM capacitors 202(1)-202(6).

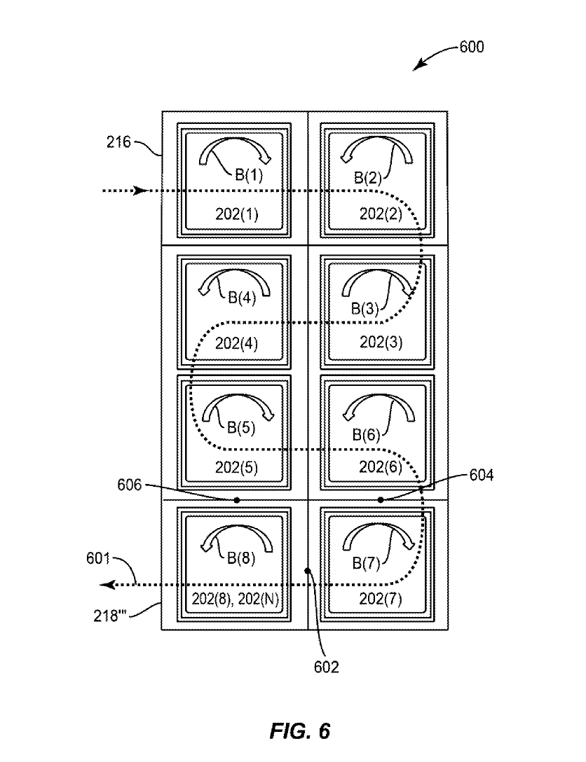

In addition to the capacitor circuit 500 in FIG. 5, FIG. 6 illustrates a top-level view diagram of an exemplary capacitor circuit 600 employing eight (8) vertically stacked MIM capacitors 202(1)-202(8), which are connected in series and arranged in a pattern 601 similar to the patterns 401 and 501 in FIGS. 4A and 5, respectively (e.g., a sinusoidal-shape pattern). The vertically stacked MIM capacitors 202(1)-202(6) are included in the circuit 600 in the same configuration as described in relation to the circuit 500 in FIG. 5, and thus are not re-described herein. In this manner, the vertically stacked MIM capacitor 202(7) is disposed electromagnetically adjacent to the vertically stacked MIM capacitors 202(6), 202(8) on the substrate (not shown), and is serially connected to the vertically stacked MIM capacitor 202(6). Additionally, the vertically stacked MIM capacitor 202(8) is disposed electromagnetically adjacent to the vertically stacked MIM capacitors 202(5), 202(7) on the substrate, and is serially connected to the vertically stacked MIM capacitor 202(7). Using this configuration, the first port 216 is still provided in the vertically stacked MIM capacitor 202(1), but a second port 218′″ is provided in the vertically stacked MIM capacitor 202(8). As previously described, the pattern 601 may employ any even number (N) of vertically stacked MIM capacitors 202(1)-202(N), as noted in the circuit 600.

With continuing reference to FIG. 6, the pattern 601 results in a larger proportion of magnetic fields B(1)-B(8) cancelling out one another rather than combining. Particularly, in addition to the properties of the magnetic fields B(1)-B(6) previously described in FIG. 5, the magnetic fields B(7), B(8) are generated in electromagnetically adjacent, vertically stacked MIM capacitors 202(7), 202(8), and rotate away from one another. Thus, the magnetic fields B(7), B(8) cancel out one another, thereby decreasing ESL at a point 602. Conversely, the magnetic fields B(6), B(7) are generated in electromagnetically adjacent, vertically stacked MIM capacitors 202(6), 202(7), and rotate away from one another. Thus, the magnetic fields B(6), B(7) cancel out one another, thereby decreasing ESL at a point 604. Further, the magnetic fields B(5), B(8) are generated in electromagnetically adjacent, vertically stacked MIM capacitors 202(5), 202(8), and rotate away from one another. Thus, the magnetic fields B(5), B(8) cancel out one another, thereby decreasing ESL at a point 606. Because the ESL is decreased at the eight (8) points 404, 406, 408, 504, 506, 602, 604, and 606, and only increased at the two (2) points 402, 502, the overall ESL of the circuit 600 decreases due to the serial connection in conjunction with the pattern 601 of the vertically stacked MIM capacitors 202(1)-202(8).

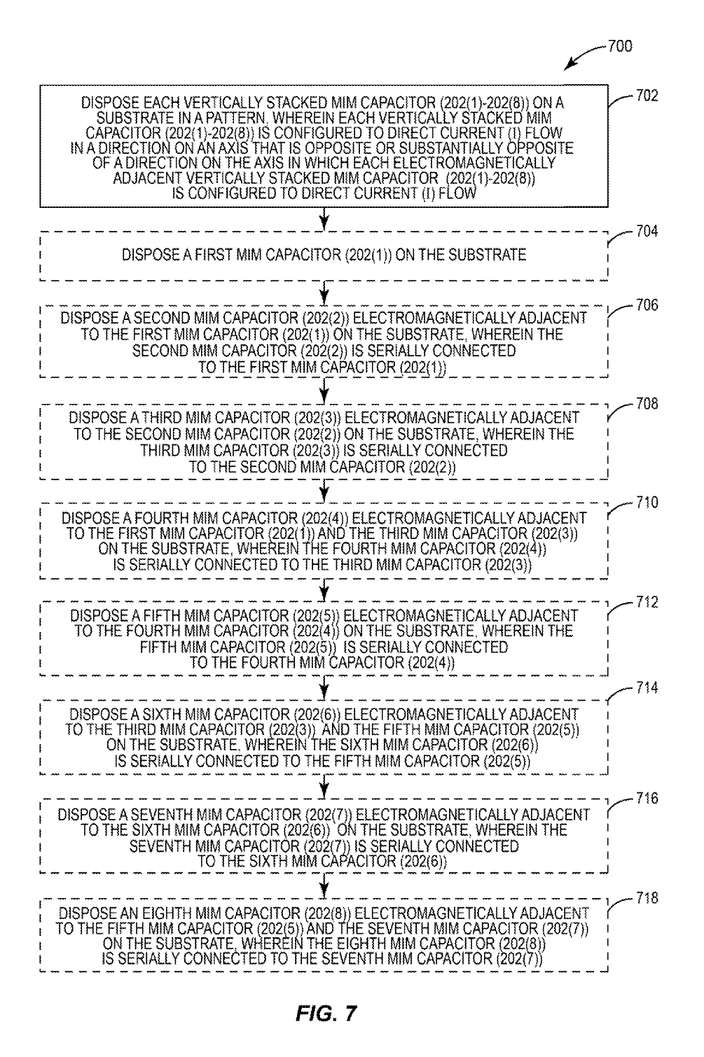

In this regard, FIG. 7 illustrates a flowchart of an exemplary process 700 that can be employed to arrange the four (4), six (6), or eight (8) vertically stacked MIM capacitors 202(1)-202(8) in FIG. 4A, 5, or 6 in the patterns 401, 501, and 601, respectively. Generally, the process 700 includes disposing each vertically stacked MIM capacitor 202(1)-202(8) connected in series on a substrate in a pattern (block 702). To achieve the pattern in block 702, each vertically stacked MIM capacitor 202(1)-202(8) is configured to direct current (I) flow in a direction on an axis that is opposite or substantially opposite of a direction on the axis in which each electromagnetically adjacent vertically stacked MIM capacitor 202(1)-202(8) is configured to direct current (I) flow. As previously described, the axis in which the current (I) flow is directed is the vertical axis in aspects disclosed herein. Further, in block 702, a vertically stacked MIM capacitor 202(1)-202(8) is disposed so as to be electromagnetically adjacent to at least two (2) vertically stacked MIM capacitors 202(1)-202(8).

With continuing reference to FIG. 7, as previously described, the process 700 can be employed to arrange the four (4) vertically stacked MIM capacitors 202(1)-202(4) in FIG. 3A in the pattern 401. To provide clarity, the vertically stacked MIM capacitors 202(1)-202(4) are also referred to herein as a first MIM capacitor 202(1), a second MIM capacitor 202(2), a third MIM capacitor 202(3), and a fourth MIM capacitor 202(4), respectively. In this manner, the step in block 702 includes disposing the first MIM capacitor 202(1) on the substrate (block 704). The step in block 702 further includes disposing the second MIM capacitor 202(2) electromagnetically adjacent to the first MIM capacitor 202(1) on the substrate, wherein the second MIM capacitor 202(2) is serially connected to the first MIM capacitor 202(1) (block 706). The step in block 702 also includes disposing the third MIM capacitor 202(3) electromagnetically adjacent to the second MIM capacitor 202(2) on the substrate, wherein the third MIM capacitor 202(3) is serially connected to the second MIM capacitor 202(2) (block 708). Additionally, the step in block 702 includes disposing the fourth MIM capacitor 202(4) electromagnetically adjacent to the first MIM capacitor 202(1) and the third MIM capacitor 202(3) on the substrate, wherein the fourth MIM capacitor 202(4) is serially connected to the third MIM capacitor 202(3) (block 710).

With continuing reference to FIG. 7, to arrange the six (6) vertically stacked MIM capacitors 202(1)-202(6) in FIG. 5 in the pattern 501, the disposing step in block 702 may include disposing the vertically stacked MIM capacitors 202(5), 202(6) in addition to the vertically stacked MIM capacitors 202(1)-202(4). For clarity, the vertically stacked MIM capacitors 202(5), 202(6) are also referred to herein as a fifth MIM capacitor 202(5) and a sixth MIM capacitor 202(6). In this manner, the step in block 702 includes disposing a fifth MIM capacitor 202(5) electromagnetically adjacent to the fourth MIM capacitor 202(4) on the substrate, wherein the fifth MIM capacitor 202(5) is serially connected to the fourth MIM capacitor 202(4) (block 712). Further, the step in block 702 includes disposing a sixth MIM capacitor 202(6) electromagnetically adjacent to the third MIM capacitor 202(3) and the fifth MIM capacitor 202(5) on the substrate, wherein the sixth MIM capacitor 202(6) is serially connected to the fifth MIM capacitor 202(5) (block 714).

Similarly, with continuing reference to FIG. 7, to arrange the eight (8) vertically stacked MIM capacitors 202(1)-202(8) in FIG. 6 in the pattern 601, the disposing step in block 702 may include disposing the vertically stacked MIM capacitors 202(7), 202(8) in addition to the vertically stacked MIM capacitors 202(1)-202(6). For clarity, the vertically stacked MIM capacitors 202(7), 202(8) are also referred to herein as a seventh MIM capacitor 202(7) and an eighth MIM capacitor 202(8). In this manner, the step in block 702 includes disposing the seventh MIM capacitor 202(7) electromagnetically adjacent to the sixth MIM capacitor 202(6) on the substrate, wherein the seventh MIM capacitor 202(7) is serially connected to the sixth MIM capacitor 202(6) (block 716). The step in block 702 also includes disposing the eighth MIM capacitor 202(8) electromagnetically adjacent to the fifth MIM capacitor 202(5) and the seventh MIM capacitor 202(7) on the substrate, wherein the eighth MIM capacitor 202(8) is serially connected to the seventh MIM capacitor 202(7) (block 718). Thus, the process 700 may be employed to arrange particular combinations of the vertically stacked MIM capacitors 202(1)-202(8) in the patterns 401, 501, and 601 (e.g., the sinusoidal-shape pattern in aspects described herein) to reduce the overall ESL of corresponding circuits.

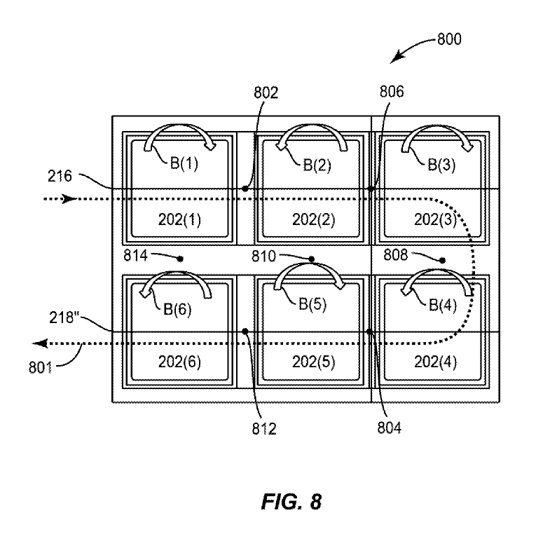

In addition to the patterns 401, 501, and 601 described in FIGS. 4-7, the vertically stacked MIM capacitors 202(1)-202(6) may be arranged in an alternative pattern 801 to achieve similar reductions in ESL. In this regard, FIG. 8 illustrates a top-level view diagram of a capacitor circuit 800 employing the vertically stacked MIM capacitors 202(1)-202(6), which are serially connected and arranged in the alternative pattern 801, wherein the pattern 801 is an alternative sinusoidal-shape pattern. To achieve the alternative pattern 801 of the circuit 800, the vertically stacked MIM capacitor 202(1) is disposed on a substrate (not shown). The vertically stacked MIM capacitor 202(2) is disposed electromagnetically adjacent to the vertically stacked MIM capacitors 202(1), 202(3), and 202(5) on the substrate, and is serially connected to the vertically stacked MIM capacitor 202(1). Further, the vertically stacked MIM capacitor 202(3) is disposed electromagnetically adjacent to the vertically stacked MIM capacitors 202(2), 202(4) on the substrate, and is serially connected to the vertically stacked MIM capacitor 202(2). Similarly, the vertically stacked MIM capacitor 202(4) is disposed electromagnetically adjacent to the vertically stacked MIM capacitors 202(3), 202(5) on the substrate, and is serially connected to the vertically stacked MIM capacitor 202(3). The vertically stacked MIM capacitor 202(5) is disposed electromagnetically adjacent to the vertically stacked MIM capacitors 202(2), 202(4), and 202(6) on the substrate, and is serially connected to the vertically stacked MIM capacitor 202(4). Further, the vertically stacked MIM capacitor 202(6) is disposed electromagnetically adjacent to the vertically stacked MIM capacitors 202(1), 202(5) on the substrate, and is serially connected to the vertically stacked MIM capacitor 202(5). Using this configuration, the first port 216 is still provided in the vertically stacked MIM capacitor 202(1), and the second port 218″ is provided in the vertically stacked MIM capacitor 202(6).

With continuing reference to FIG. 8, by arranging the vertically stacked MIM capacitors 202(1)-202(6) in the alternative pattern 801 as described above, the ESL attributable to the magnetic fields B(1)-B(6) is reduced. Particularly, the alternative pattern 801 results in a larger proportion of the magnetic fields B(1)-B(6) cancelling out one another rather than combining, thus decreasing ESL upon the circuit 800 receiving the current (I). In particular, similar to previous descriptions of the magnetic fields B(1)-B(6), the rotational direction of the magnetic fields B(1)-B(6) causes the corresponding magnetic fields B(1)-B(6) at points 802, 804 to combine, thereby increasing ESL associated with the points 802, 804. Conversely, the rotational direction of the magnetic fields B(1)-B(6) causes the magnetic fields B(1)-B(6) to cancel out one another at points 806, 808, 810, 812, and 814, thereby decreasing associated levels of ESL. Because the ESL is decreased at the five (5) points 806, 808, 810, 812, and 814, and only increased at the two (2) points 802, 804, the overall ESL of the circuit 800 decreases due to the serial connection in conjunction with the alternative pattern 801 of the vertically stacked MIM capacitors 202(1)-202(6). Therefore, connecting the vertically stacked MIM capacitors 202(1)-202(6) in series improves the linearity of the vertically stacked MIM capacitors 202(1)-202(6), while the arrangement in the alternative pattern 801 reduces a corresponding increase in ESL otherwise generated in the linear pattern.

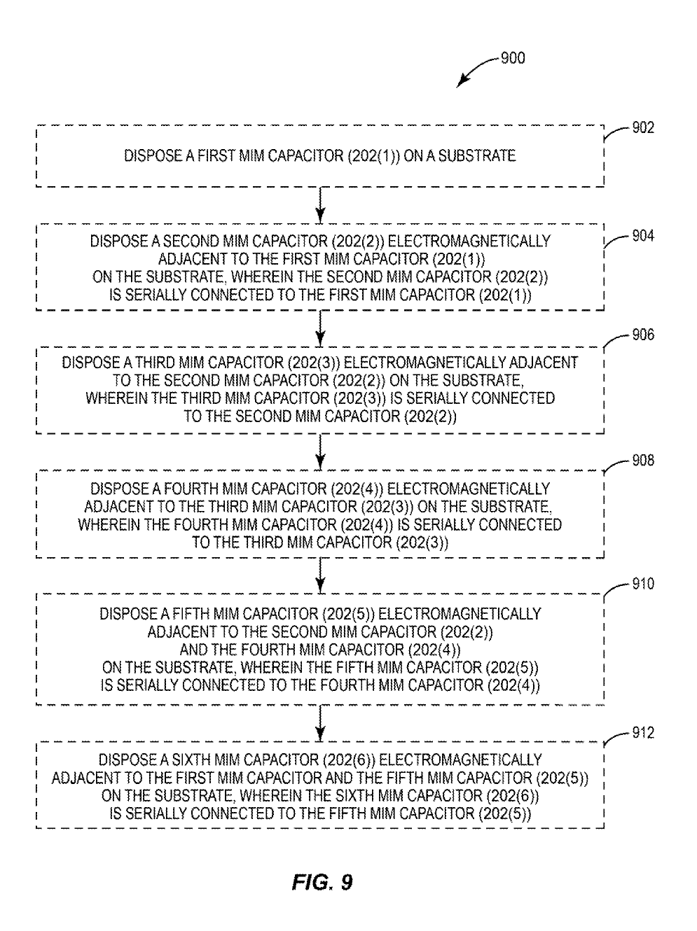

In this regard, FIG. 9 illustrates a flowchart of an exemplary process 900 that can be employed to arrange the six (6) vertically stacked MIM capacitors 202(1)-202(6) in FIG. 8 in the alternative pattern 801. Specifically, the process 900 illustrates steps that may be employed in the disposing step in block 702 in FIG. 7. The process 900 includes disposing the first MIM capacitor 202(1) on the substrate (block 902). The process 900 further includes disposing the second MIM capacitor 202(2) electromagnetically adjacent to the first MIM capacitor 202(1) on the substrate, wherein the second MIM capacitor 202(2) is serially connected to the first MIM capacitor 202(1) (block 904). Additionally, the process 900 includes disposing the third MIM capacitor 202(3) electromagnetically adjacent to the second MIM capacitor 202(2) on the substrate, wherein the third MIM capacitor 202(3) is serially connected to the second MIM capacitor 202(2) (block 906). The process 900 also includes disposing the fourth MIM capacitor 202(4) electromagnetically adjacent to the third MIM capacitor 202(3) on the substrate, wherein the fourth MIM capacitor 202(4) is serially connected to the third MIM capacitor 202(3) (block 908). The process 900 further includes disposing the fifth MIM capacitor 202(5) electromagnetically adjacent to the second MIM capacitor 202(2) and the fourth MIM capacitor 202(4) on the substrate, wherein the fifth MIM capacitor 202(5) is serially connected to the fourth MIM capacitor 202(4) (block 910). Finally, the process 900 includes disposing the sixth MIM capacitor 202(6) electromagnetically adjacent to the first MIM capacitor 202(1) and the fifth MIM capacitor 202(5) on the substrate, wherein the sixth MIM capacitor 202(6) is serially connected to the fifth MIM capacitor 202(5) (block 912). In this manner, the process 900 may be employed to arrange the vertically stacked MIM capacitors 202(1)-202(6) in the alternative pattern 801 to reduce the overall ESL of corresponding circuits.

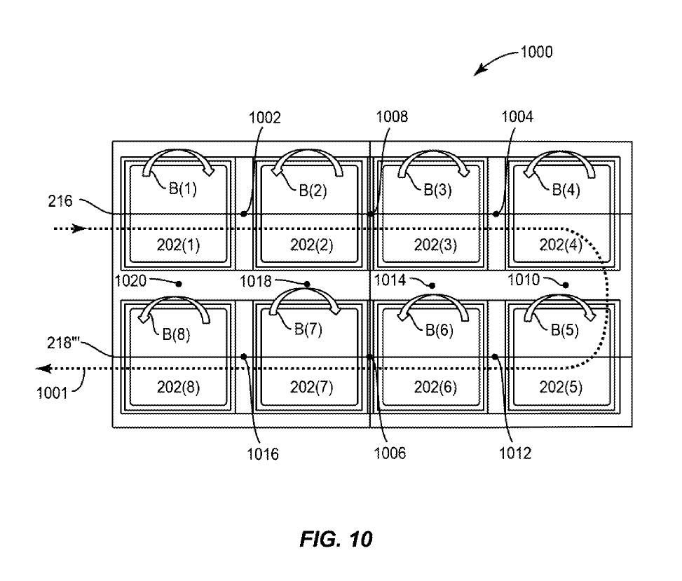

In addition to the aspects previously described, FIG. 10 illustrates a top-level view diagram of a capacitor circuit 1000 employing the vertically stacked MIM capacitors 202(1)-202(8), which are serially connected and arranged in an alternative pattern 1001 similar to the alternative pattern 801 in FIG. 8. To achieve the alternative pattern 1001 of the circuit 1000, the vertically stacked MIM capacitor 202(1) is disposed on a substrate (not shown). The vertically stacked MIM capacitor 202(2) is disposed electromagnetically adjacent to the vertically stacked MIM capacitors 202(1), 202(3), and 202(7) on the substrate, and is serially connected to the vertically stacked MIM capacitor 202(1). The vertically stacked MIM capacitor 202(3) is disposed electromagnetically adjacent to the vertically stacked MIM capacitors 202(2), 202(4), and 202(6) on the substrate, and is serially connected to the vertically stacked MIM capacitor 202(2). Further, the vertically stacked MIM capacitor 202(4) is disposed electromagnetically adjacent to the vertically stacked MIM capacitors 202(3), 202(5) on the substrate, and is serially connected to the vertically stacked MIM capacitor 202(3).

With continuing reference to FIG. 10, the vertically stacked MIM capacitor 202(5) is disposed electromagnetically adjacent to the vertically stacked MIM capacitors 202(4), 202(6) on the substrate, and is serially connected to the vertically stacked MIM capacitor 202(4). Additionally, the vertically stacked MIM capacitor 202(6) is disposed electromagnetically adjacent to the vertically stacked MIM capacitors 202(3), 202(5), and 202(7) on the substrate, and is serially connected to the vertically stacked MIM capacitor 202(5). The vertically stacked MIM capacitor 202(7) is disposed electromagnetically adjacent to the vertically stacked MIM capacitors 202(2), 202(6), and 202(8) on the substrate, and is serially connected to the vertically stacked MIM capacitor 202(6). The vertically stacked MIM capacitor 202(8) is disposed electromagnetically adjacent to the vertically stacked MIM capacitors 202(1), 202(7) on the substrate, and is serially connected to the vertically stacked MIM capacitor 202(7). Using this configuration, the first port 216 is provided in the vertically stacked MIM capacitor 202(1), and the second port 218′″ is provided in the vertically stacked MIM capacitor 202(8).

With continuing reference to FIG. 10, by arranging the vertically stacked MIM capacitors 202(1)-202(8) in the alternative pattern 1001 as described above, the ESL attributable to the magnetic fields B(1)-B(8) is reduced. Particularly, the alternative pattern 1001 results in a larger proportion of the magnetic fields B(1)-B(8) cancelling out one another rather than combining, thus decreasing ESL upon the circuit 1000 receiving the current (I). In particular, similar to previous descriptions of the magnetic fields B(1)-B(8), the rotational direction of the magnetic fields B(1)-B(8) causes the corresponding magnetic fields B(1)-B(8) at points 1002, 1004, and 1006 to combine, thereby increasing ESL associated with the points 1002, 1004, and 1006. Conversely, the rotational direction of the magnetic fields B(1)-B(8) causes the magnetic fields B(1)-B(8) to cancel out one another at points 1008, 1010, 1012, 1014, 1016, 1018, and 1020, thereby decreasing associated levels of ESL. Because the ESL is decreased at the seven (7) points listed above, and only increased at the three (3) points listed above, the overall ESL of the circuit 1000 decreases due to the serial connection in conjunction with the alternative pattern 1001 of the vertically stacked MIM capacitors 202(1)-202(8). Therefore, connecting the vertically stacked MIM capacitors 202(1)-202(8) in series improves the linearity of the vertically stacked MIM capacitors 202(1)-202(8), while the arrangement in the alternative pattern 1001 reduces a corresponding increase in ESL otherwise generated in the linear pattern.

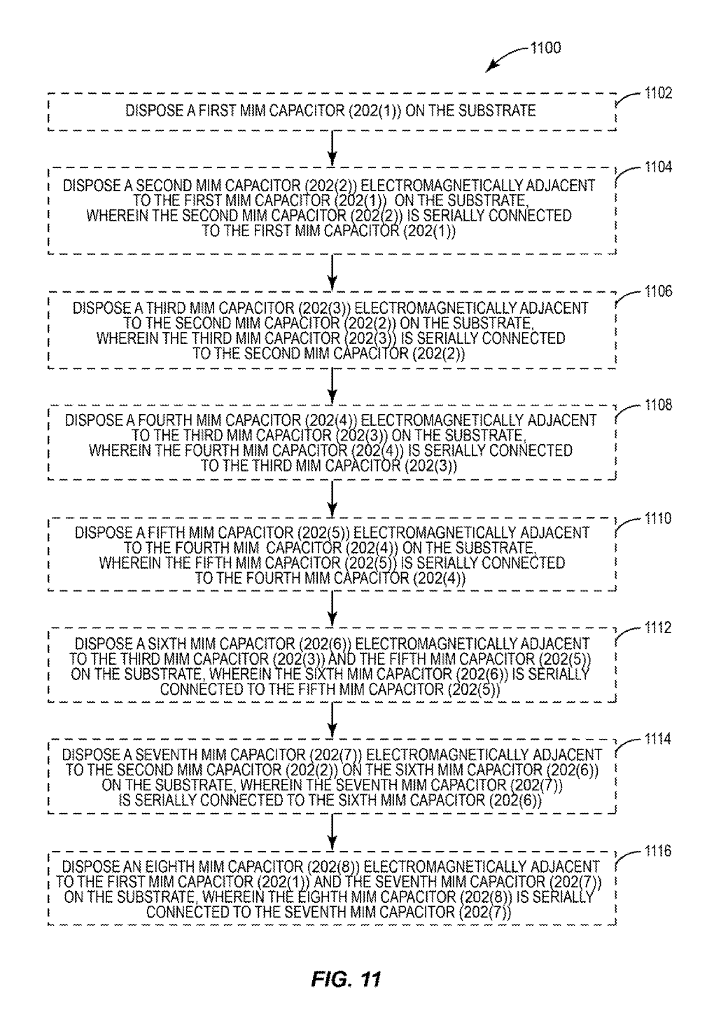

In this regard, FIG. 11 illustrates a flowchart of an exemplary process 1100 that can be employed to arrange the eight (8) vertically stacked MIM capacitors 202(1)-202(8) in FIG. 10 in the alternative pattern 1001 in FIG. 10. Specifically, the process 1100 illustrates steps that may be employed in the disposing step in block 702 in FIG. 7. The process 1100 includes disposing the first MIM capacitor 202(1) on a substrate (block 1102). The process 1100 also includes disposing the second MIM capacitor 202(2) electromagnetically adjacent to the first MIM capacitor 202(1) on the substrate, wherein the second MIM capacitor 202(2) is serially connected to the first MIM capacitor 202(1) (block 1104). Further, the process 1100 includes disposing the third MIM capacitor 202(3) electromagnetically adjacent to the second MIM capacitor 202(2) on the substrate, wherein the third MIM capacitor 202(3) is serially connected to the second MIM capacitor 202(2) (block 1106). The process 1100 also includes disposing the fourth MIM capacitor 202(4) electromagnetically adjacent to the third MIM capacitor 202(3) on the substrate, wherein the fourth MIM capacitor 202(4) is serially connected to the third MIM capacitor 202(3) (block 1108).

With continuing reference to FIG. 11, the process 1100 further includes disposing the fifth MIM capacitor 202(5) electromagnetically adjacent to the fourth MIM capacitor 202(4) on the substrate, wherein the fifth MIM capacitor 202(5) is serially connected to the fourth MIM capacitor 202(4) (block 1110). The process 1100 includes disposing a sixth MIM capacitor 202(6) electromagnetically adjacent to the third MIM capacitor 202(3) and the fifth MIM capacitor 202(5) on the substrate, wherein the sixth MIM capacitor 202(6) is serially connected to the fifth MIM capacitor 202(5) (block 1112). Further, the process 1100 includes disposing the seventh MIM capacitor 202(7) electromagnetically adjacent to the second MIM capacitor 202(2) and the sixth MIM capacitor 202(6) on the substrate, wherein the seventh MIM capacitor 202(7) is serially connected to the sixth MIM capacitor 202(6) (block 1114). Additionally, the process 1100 includes disposing the eighth MIM capacitor 202(8) electromagnetically adjacent to the first MIM capacitor 202(1) and the seventh MIM capacitor 202(7) on the substrate, wherein the eighth MIM capacitor 202(8) is serially connected to the seventh MIM capacitor 202(7) (block 1116). In this manner, the process 1100 may be employed to arrange the vertically stacked MIM capacitors 202(1)-202(8) in the alternative pattern 1001 to reduce the overall ESL of corresponding circuits.

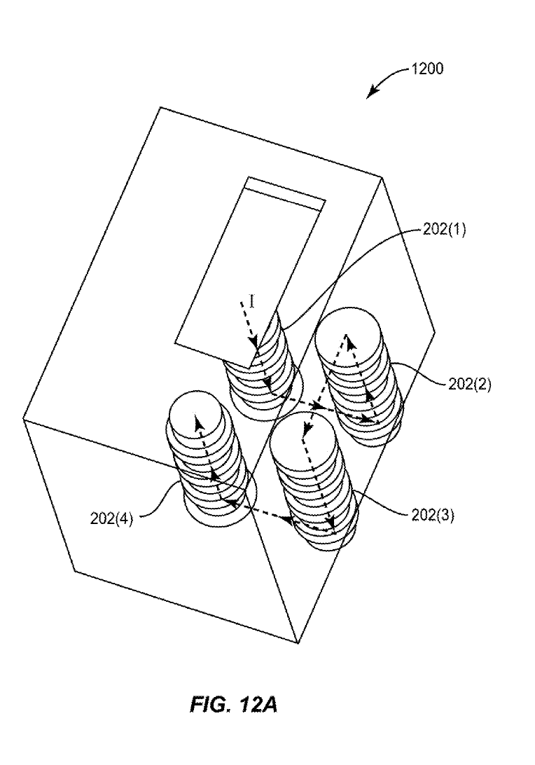

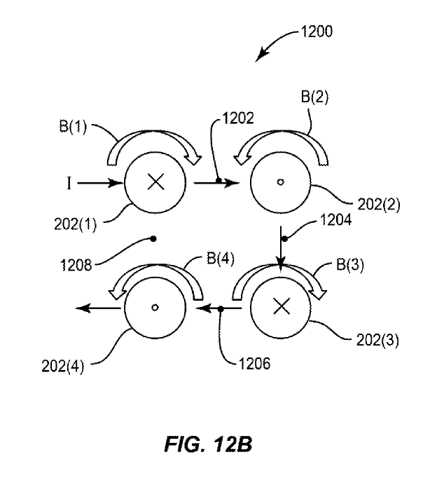

Aspects disclosed in FIGS. 4-11 focus on various combinations of the vertically stacked MIM capacitors 202(1)-202(8) employed in an electrical planar technology. However, alternative aspects may include the vertically stacked MIM capacitors 202(1)-202(8) employed in other technologies. In this regard, FIG. 12A illustrates a three-dimensional view diagram of an exemplary capacitor circuit 1200 employing the vertically stacked MIM capacitors 202(1)-202(4) connected in series in a coreless substrate technology and arranged in a pattern to reduce ESL. Notably, the vertically stacked MIM capacitors 202(1)-202(4) are arranged in the same pattern 401 as previously described in FIG. 4A, causing the current (I) to flow in similar directions on the vertical axis. In this manner, FIG. 12B illustrates a top-level view diagram of the capacitor circuit 1200 in FIG. 12A. Similar to the previous description of FIG. 4A, the rotational direction of the magnetic fields B(1)-B(4) in the circuit 1200 results in a larger proportion of the magnetic fields B(1)-B(4) cancelling out one another rather than combining, thus decreasing ESL upon the circuit 1200 receiving the current (I). Particularly, the rotational direction of the magnetic fields B(1)-B(4) cause the corresponding magnetic fields B(1)-B(4) at point 1202 to combine, thereby increasing ESL associated with the point 1202. Conversely, the rotational direction of the magnetic fields B(1)-B(4) cause the magnetic fields B(1)-B(4) to cancel out one another at points 1204, 1206, and 1208, thereby decreasing associated levels of ESL. Because the ESL is decreased at the three (3) points and only increased at the one (1) point, the overall ESL of the circuit 1200 decreases due to the serial connection in conjunction with the alternative pattern of the vertically stacked MIM capacitors 202(1)-202(4). Therefore, employing the vertically stacked MIM capacitors 202(1)-202(4) in the coreless substrate technology in the pattern provides similar ESL reduction as achieved when using the electrical planar technology.

Notably, the aspects described herein employ vertically stacked MIM capacitors. However, other aspects may employ other types of MIM capacitors in the patterns 401, 501, 601 and the alternative patterns 801, 1001 to achieve similar ESL reduction. Specifically, as a non-limiting example, other aspects may employ single layer MIM capacitors in the patterns 401, 501, 601 or the alternative patterns 801, 1001, as opposed to vertically stacked MIM capacitors, and achieve similar functionality.

The MIM capacitors arranged in a pattern to reduce inductance according to aspects disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

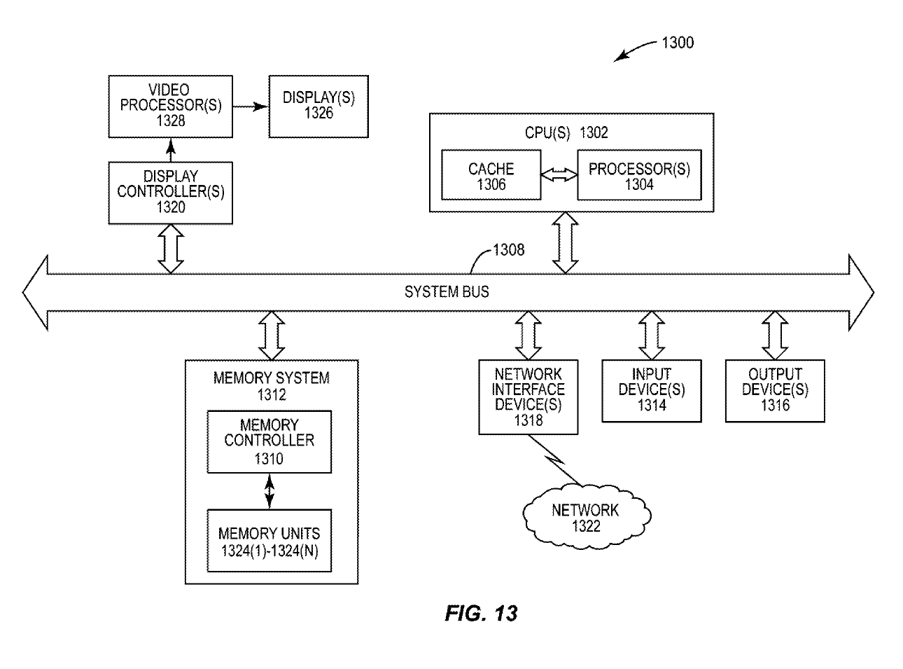

In this regard, FIG. 13 illustrates an example of a processor-based system 1300 that can employ the vertically stacked MIM capacitors 202(1)-202(8) illustrated in FIGS. 4, 5, 6, 8, 10, 12A, and 12B. In this example, the processor-based system 1300 includes one or more central processing units (CPUs) 1302, each including one or more processors 1304. The CPU(s) 1302 may have cache memory 1306 coupled to the processor(s) 1304 for rapid access to temporarily stored data. The CPU(s) 1302 is coupled to a system bus 1308 and can intercouple master and slave devices included in the processor-based system 1300. As is well known, the CPU(s) 1302 communicates with these other devices by exchanging address, control, and data information over the system bus 1308. For example, the CPU(s) 1302 can communicate bus transaction requests to a memory controller 1310 as an example of a slave device. Although not illustrated in FIG. 13, multiple system buses 1308 could be provided, wherein each system bus 1308 constitutes a different fabric.

Other master and slave devices can be connected to the system bus 1308. As illustrated in FIG. 13, these devices can include a memory system 1312, one or more input devices 1314, one or more output devices 1316, one or more network interface devices 1318, and one or more display controllers 1320, as examples. The input device(s) 1314 can include any type of input device, including but not limited to input keys, switches, voice processors, etc. The output device(s) 1316 can include any type of output device, including but not limited to audio, video, other visual indicators, etc. The network interface device(s) 1318 can be any devices configured to allow exchange of data to and from a network 1322. The network 1322 can be any type of network, including but not limited to a wired or wireless network, a private or public network, a local area network (LAN), a wide local area network (WLAN), and the Internet. The network interface device(s) 1318 can be configured to support any type of communications protocol desired. The memory system 1312 can include one or more memory units 1324(1)-1324(N).

The CPU(s) 1302 may also be configured to access the display controller(s) 1320 over the system bus 1308 to control information sent to one or more displays 1326. The display controller(s) 1320 sends information to the display(s) 1326 to be displayed via one or more video processors 1328, which process the information to be displayed into a format suitable for the display(s) 1326. The display(s) 1326 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A capacitor circuit comprising:
a plurality of metal-insulator-metal (MIM) capacitors coupled in series and arranged in a circuit in a pattern;
wherein each MIM capacitor among the plurality of MIM capacitors is configured to direct current flow in a direction on an axis that is opposite or substantially opposite of a direction on the axis in which each electromagnetically adjacent MIM capacitor among the plurality of MIM capacitors is configured to direct current flow; and
wherein a MIM capacitor is electromagnetically adjacent to at least two (2) MIM capacitors.

2. The capacitor circuit of claim 1, wherein the pattern comprises a sinusoidal-shape pattern.

3. The capacitor circuit of claim 1, wherein the pattern is configured to reduce inductance of the circuit.

4. The capacitor circuit of claim 1, wherein the plurality of MIM capacitors comprises an even number of MIM capacitors.

5. The capacitor circuit of claim 1, wherein the plurality of MIM capacitors comprises four (4) MIM capacitors.

6. The capacitor circuit of claim 1, wherein the plurality of MIM capacitors comprises six (6) MIM capacitors.

7. The capacitor circuit of claim 1, wherein the plurality of MIM capacitors comprises eight (8) MIM capacitors.

8. The capacitor circuit of claim 1, wherein the plurality of MIM capacitors comprises:
a first MIM capacitor among the plurality of MIM capacitors disposed on a substrate;
a second MIM capacitor among the plurality of MIM capacitors disposed electromagnetically adjacent to the first MIM capacitor on the substrate, wherein the second MIM capacitor is serially connected to the first MIM capacitor;
a third MIM capacitor among the plurality of MIM capacitors disposed electromagnetically adjacent to the second MIM capacitor on the substrate, wherein the third MIM capacitor is serially connected to the second MIM capacitor; and
a fourth MIM capacitor among the plurality of MIM capacitors disposed electromagnetically adjacent to the first MIM capacitor and the third MIM capacitor on the substrate, wherein the fourth MIM capacitor is serially connected to the third MIM capacitor.

9. The capacitor circuit of claim 8, wherein the plurality of MIM capacitors further comprises:
a fifth MIM capacitor among the plurality of MIM capacitors disposed electromagnetically adjacent to the fourth MIM capacitor on the substrate, wherein the fifth MIM capacitor is serially connected to the fourth MIM capacitor; and
a sixth MIM capacitor among the plurality of MIM capacitors disposed electromagnetically adjacent to the third MIM capacitor and the fifth MIM capacitor on the substrate, wherein the sixth MIM capacitor is serially connected to the fifth MIM capacitor.

10. The capacitor circuit of claim 9, wherein the plurality of MIM capacitors further comprises:
a seventh MIM capacitor among the plurality of MIM capacitors disposed electromagnetically adjacent to the sixth MIM capacitor on the substrate, wherein the seventh MIM capacitor is serially connected to the sixth MIM capacitor; and
an eighth MIM capacitor among the plurality of MIM capacitors disposed electromagnetically adjacent to the fifth MIM capacitor and the seventh MIM capacitor on the substrate, wherein the eighth MIM capacitor is serially connected to the seventh MIM capacitor.

11. The capacitor circuit of claim 1, wherein the plurality of MIM capacitors comprises:
a first MIM capacitor among the plurality of MIM capacitors disposed on a substrate;
a second MIM capacitor among the plurality of MIM capacitors disposed electromagnetically adjacent to the first MIM capacitor on the substrate, wherein the second MIM capacitor is serially connected to the first MIM capacitor;
a third MIM capacitor among the plurality of MIM capacitors disposed electromagnetically adjacent to the second MIM capacitor on the substrate, wherein the third MIM capacitor is serially connected to the second MIM capacitor;
a fourth MIM capacitor among the plurality of MIM capacitors disposed electromagnetically adjacent to the third MIM capacitor on the substrate, wherein the fourth MIM capacitor is serially connected to the third MIM capacitor;
a fifth MIM capacitor among the plurality of MIM capacitors disposed electromagnetically adjacent to the second MIM capacitor and the fourth MIM capacitor on the substrate, wherein the fifth MIM capacitor is serially connected to the fourth MIM capacitor; and
a sixth MIM capacitor among the plurality of MIM capacitors disposed electromagnetically adjacent to the first MIM capacitor and the fifth MIM capacitor on the substrate, wherein the sixth MIM capacitor is serially connected to the fifth MIM capacitor.

12. The capacitor circuit of claim 1, wherein the plurality of MIM capacitors comprises:
a first MIM capacitor among the plurality of MIM capacitors disposed on a substrate;
a second MIM capacitor among the plurality of MIM capacitors disposed electromagnetically adjacent to the first MIM capacitor on the substrate, wherein the second MIM capacitor is serially connected to the first MIM capacitor;
a third MIM capacitor among the plurality of MIM capacitors disposed electromagnetically adjacent to the second MIM capacitor on the substrate, wherein the third MIM capacitor is serially connected to the second MIM capacitor;
a fourth MIM capacitor among the plurality of MIM capacitors disposed electromagnetically adjacent to the third MIM capacitor on the substrate, wherein the fourth MIM capacitor is serially connected to the third MIM capacitor;
a fifth MIM capacitor among the plurality of MIM capacitors disposed electromagnetically adjacent to the fourth MIM capacitor on the substrate, wherein the fifth MIM capacitor is serially connected to the fourth MIM capacitor;
a sixth MIM capacitor among the plurality of MIM capacitors disposed electromagnetically adjacent to the third MIM capacitor and the fifth MIM capacitor on the substrate, wherein the sixth MIM capacitor is serially connected to the fifth MIM capacitor;
a seventh MIM capacitor among the plurality of MIM capacitors disposed electromagnetically adjacent to the second MIM capacitor and the sixth MIM capacitor on the substrate, wherein the seventh MIM capacitor is serially connected to the sixth MIM capacitor; and
an eighth MIM capacitor among the plurality of MIM capacitors disposed electromagnetically adjacent to the first MIM capacitor and the seventh MIM capacitor on the substrate, wherein the eighth MIM capacitor is serially connected to the seventh MIM capacitor.

13. The capacitor circuit of claim 1, wherein each MIM capacitor among the plurality of MIM capacitors comprises a single layer MIM capacitor, comprising:
a first metal layer disposed on top of a substrate;
a first dielectric layer disposed on top of the first metal layer; and
a second metal layer disposed on top of the first dielectric layer.

14. The capacitor circuit of claim 1, wherein each MIM capacitor among the plurality of MIM capacitors comprises a vertically stacked MIM capacitor, comprising:
a first metal layer disposed on top of a substrate;
a first dielectric layer disposed on top of the first metal layer;
a second metal layer disposed on top of the first dielectric layer;
a second dielectric layer disposed on top of the second metal layer;
a third metal layer disposed on top of the second dielectric layer; and
a port comprising a partition of a fourth metal layer coupled to the third metal layer.

15. The circuit of claim 1, wherein the plurality of MIM capacitors employs an electrical planar technology.

16. The capacitor circuit of claim 1, wherein the plurality of MIM capacitors employs a coreless substrate technology.

17. The capacitor circuit of claim 1 integrated into an integrated circuit (IC).

18. The capacitor circuit of claim 1 integrated into a device selected from the group consisting of: a set top box; an entertainment unit; a navigation device; a communications device; a fixed location data unit; a mobile location data unit; a mobile phone; a cellular phone; a computer; a portable computer; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; and a portable digital video player.

19. A capacitor circuit comprising:
a means for arranging a plurality of metal-insulator-metal (MIM) capacitors coupled in series on a substrate in a pattern;
wherein each MIM capacitor among the plurality of MIM capacitors is configured to direct current flow in a direction on an axis that is opposite or substantially opposite of a direction on the axis in which each electromagnetically adjacent MIM capacitor among the plurality of MIM capacitors is configured to direct current flow; and
wherein a MIM capacitor is electromagnetically adjacent to at least two (2) MIM capacitors.

20. A method of arranging a plurality of metal-insulator-metal (MIM) capacitors in a circuit, comprising:
disposing each MIM capacitor among a plurality of MIM capacitors coupled in series on a substrate in a pattern;
wherein each MIM capacitor among the plurality of MIM capacitors is configured to direct current flow in a direction on an axis that is opposite or substantially opposite of a direction on the axis in which each electromagnetically adjacent MIM capacitor among the plurality of MIM capacitors is configured to direct current flow; and
wherein a MIM capacitor is electromagnetically adjacent to at least two (2) MIM capacitors.

21. The method claim 20, wherein the pattern comprises a sinusoidal-shape pattern.

22. The method of claim 20, wherein the pattern is configured to reduce inductance of the circuit.

23. The method of claim 20, wherein disposing each MIM capacitor comprises:
disposing a first MIM capacitor among the plurality of MIM capacitors on a substrate;
disposing a second MIM capacitor among the plurality of MIM capacitors adjacent to the first MIM capacitor on the substrate, wherein the second MIM capacitor is serially connected to the first MIM capacitor;
disposing a third MIM capacitor among the plurality of MIM capacitors adjacent to the second MIM capacitor on the substrate, wherein the third MIM capacitor is serially connected to the second MIM capacitor; and
disposing a fourth MIM capacitor among the plurality of MIM capacitors adjacent to the first MIM capacitor and the third MIM capacitor on the substrate, wherein the fourth MIM capacitor is serially connected to the third MIM capacitor.

24. The method of claim 23, wherein disposing each MIM capacitor further comprises:
disposing a fifth MIM capacitor among the plurality of MIM capacitors adjacent to the fourth MIM capacitor on the substrate, wherein the fifth MIM capacitor is serially connected to the fourth MIM capacitor; and
disposing a sixth MIM capacitor among the plurality of MIM capacitors adjacent to the third MIM capacitor and the fifth MIM capacitor on the substrate, wherein the sixth MIM capacitor is serially connected to the fifth MIM capacitor.

25. The method of claim 24, wherein disposing each MIM capacitor further comprises:
disposing a seventh MIM capacitor among the plurality of MIM capacitors adjacent to the sixth MIM capacitor on the substrate, wherein the seventh MIM capacitor is serially connected to the sixth MIM capacitor; and
disposing an eighth MIM capacitor among the plurality of MIM capacitors adjacent to the fifth MIM capacitor and the seventh MIM capacitor on the substrate, wherein the eighth MIM capacitor is serially connected to the seventh MIM capacitor.

26. The method of claim 20, wherein disposing each MIM capacitor comprises:
disposing a first MIM capacitor among the plurality of MIM capacitors on a substrate;
disposing a second MIM capacitor among the plurality of MIM capacitors adjacent to the first MIM capacitor on the substrate, wherein the second MIM capacitor is serially connected to the first MIM capacitor;
disposing a third MIM capacitor among the plurality of MIM capacitors adjacent to the second MIM capacitor on the substrate, wherein the third MIM capacitor is serially connected to the second MIM capacitor;
disposing a fourth MIM capacitor among the plurality of MIM capacitors adjacent to the third MIM capacitor on the substrate, wherein the fourth MIM capacitor is serially connected to the third MIM capacitor;
disposing a fifth MIM capacitor among the plurality of MIM capacitors adjacent to the second MIM capacitor and the fourth MIM capacitor on the substrate, wherein the fifth MIM capacitor is serially connected to the fourth MIM capacitor; and
disposing a sixth MIM capacitor among the plurality of MIM capacitors adjacent to the first MIM capacitor and the fifth MIM capacitor on the substrate, wherein the sixth MIM capacitor is serially connected to the fifth MIM capacitor.

27. The method of claim 20, wherein disposing each MIM capacitor comprises:
disposing a first MIM capacitor among the plurality of MIM capacitors on a substrate;
disposing a second MIM capacitor among the plurality of MIM capacitors adjacent to the first MIM capacitor on the substrate, wherein the second MIM capacitor is serially connected to the first MIM capacitor;
disposing a third MIM capacitor among the plurality of MIM capacitors adjacent to the second MIM capacitor on the substrate, wherein the third MIM capacitor is serially connected to the second MIM capacitor;
disposing a fourth MIM capacitor among the plurality of MIM capacitors adjacent to the third MIM capacitor on the substrate, wherein the fourth MIM capacitor is serially connected to the third MIM capacitor;
disposing a fifth MIM capacitor among the plurality of MIM capacitors adjacent to the fourth MIM capacitor on the substrate, wherein the fifth MIM capacitor is serially connected to the fourth MIM capacitor;
disposing a sixth MIM capacitor among the plurality of MIM capacitors adjacent to the third MIM capacitor and the fifth MIM capacitor on the substrate, wherein the sixth MIM capacitor is serially connected to the fifth MIM capacitor;
disposing a seventh MIM capacitor among the plurality of MIM capacitors adjacent to the second MIM capacitor and the sixth MIM capacitor on the substrate, wherein the seventh MIM capacitor is serially connected to the sixth MIM capacitor; and
disposing an eighth MIM capacitor among the plurality of MIM capacitors adjacent to the first MIM capacitor and the seventh MIM capacitor on the substrate, wherein the eighth MIM capacitor is serially connected to the seventh MIM capacitor.
